(19) United States
(12) Patent Application Publication
(10) Pub. No.: US 2022/0059377 A1
(43) Pub. Date: Feb. 24, 2022

(54) INSPECTION DEVICE, RESIN MOLDING APPARATUS, AND METHOD OF MANUFACTURING RESIN MOLDED PRODUCT

(71) Applicant: TOWA CORPORATION, Kyoto (JP)

(72) Inventors: Kazutaka NORIKANE, Kyoto (JP); Toshinori KASAI, Kyoto (JP); Yoshifumi ARAKI, Kyoto (JP)

(21) Appl. No.: 17/402,416

(22) Filed: Aug. 13, 2021

(30) Foreign Application Priority Data
Aug. 18, 2020 (JP) 2020-137827

(51) Int. Cl. H01L 21/67; H01L 21/56; H01L 21/66; G06T 7/00; B29C 43/58

(52) U.S. Cl. CPC H01L 21/67288; H01L 21/67126; H01L 21/565; H01L 22/12; B29C 43/36; B29C 43/58; G06T 2207/30164; G06T 2207/30116; G06T 7/0004

(57) ABSTRACT

An inspection device includes: a first light source configured to emit light through a diffusion plate; a second light source configured to emit light through a focusing optical component; and a camera configured to take an image of a resin molded substrate irradiated with the light from the first light source and the second light source.

### CROSS-REFERENCE TO RELATED APPLICATION

This application is based upon and claims the benefit of priority from Japanese Patent Application No. 2020-137827, filed on Aug. 18, 2020, the entire contents of which are incorporated herein by reference.

### TECHNICAL FIELD

The present disclosure relates to an inspection device, a resin molding apparatus, and a method of manufacturing a resin molded product.

### BACKGROUND

Patent Document 1 discloses a technique of inspecting a defect by switching two types of light sources for a workpiece.

### Prior Art Document

### Patent Document

Patent Document 1: Japanese Laid-Open Patent Publication No. 2008-202949

In Patent Document 1, the light sources are switchedly used, that is, a light source for oblique incident illumination and a light source for coaxial vertical illumination do not irradiate light simultaneously.

At present, no technique has been proposed that can detect various types of defects on a surface of a resin molded product, which is a workpiece, in a common inspection process.

### SUMMARY

An inspection device according to the present disclosure includes: a first light source configured to emit light through a diffusion plate; a second light source configured to emit light through a focusing optical component; and a camera configured to take an image of a resin molded substrate irradiated with the light from the first light source and the second light source.

A resin molding apparatus according to the present disclosure includes: a resin molding part configured to resin-mold a substrate; and the inspection device.

A method of manufacturing a resin molded product according to the present disclosure includes: a resin molding process of performing resin molding in the resin molding part by using the resin molding apparatus; and an inspection process of inspecting, by the inspection device, the resin molded substrate molded in the resin molding process.

### BRIEF DESCRIPTION OF DRAWINGS

The accompanying drawings, which are incorporated in and constitute a part of the specification, illustrate embodiments of the present disclosure.

FIG. 1 is a plan view schematically showing a configuration of a resin molding apparatus according to an embodiment of the present disclosure.

FIGS. 2A and 2B are a plan view and a side view of an inspection device according to the embodiment of the present disclosure, respectively.

FIGS. 3A to 3D are side views schematically showing inspection devices of comparative examples.

FIG. 4 is a diagram showing image data obtained by the inspection device according to the embodiment of the present disclosure and by the inspection devices of comparative examples.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiment of the Present Disclosure

Hereinafter, an embodiment of the present disclosure will be described in detail with reference to the drawings. The same or corresponding parts in the drawings are designated by like reference numerals, and the description thereof will not be repeated.

### Overall Configuration of Resin Molding Apparatus 100

A resin molding apparatus 100 according to the present embodiment is configured to manufacture a resin molded product (resin molded substrate W) by encapsulating, with a resin, a component mounting surface of a substrate T on which an electronic component such as a semiconductor chip or the like is mounted.

Examples of the substrate T include a semiconductor substrate such as a silicon wafer or the like, a lead frame, a printed wiring board, a metal substrate, a resin substrate, a glass substrate, a ceramic substrate, and the like. Further, the substrate T may be a carrier used for FOWLP (Fan-Out Wafer Level Packaging) and FOPLP (Fan-Out Panel Level Packaging). More specifically, the substrate T may be one that has already been wired or one that has not been wired.

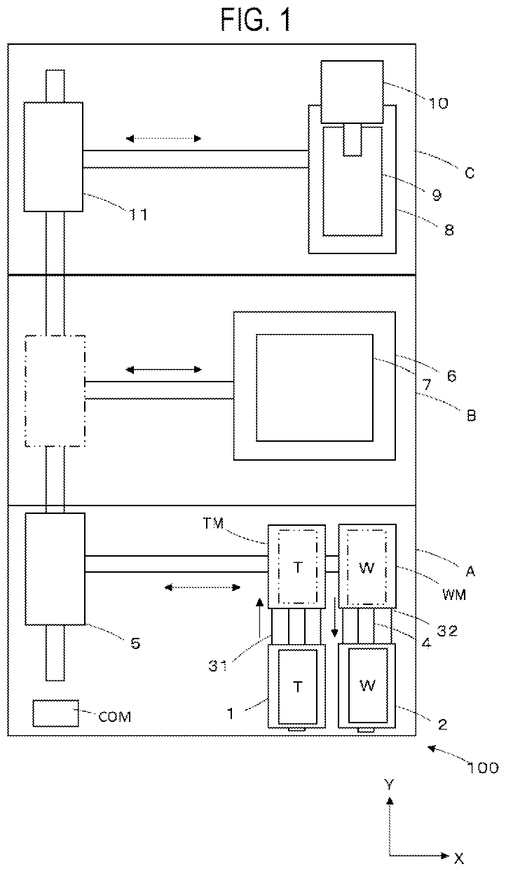

As shown in FIG. 1, the resin molding apparatus 100 includes a substrate supply/storage module A, a resin molding module B, and a resin material supply module C as components thereof. Each of the components (each of the modules A to C) is detachable and replaceable with respect to the respective components. The resin molding module B corresponds to a resin molding part.

The substrate supply/storage module A includes a substrate supply 1, a substrate storage 2, transfer paths 31 and 32, an inspection device 4, a substrate transfer mechanism 5, a substrate mount TM, a molded substrate mount WM, and a controller COM. The substrate supply 1 supplies the substrate T, which is a resin molding target before molding. The transfer path 31 is used to transfer the substrate T supplied from the substrate supply 1 in a Y direction. The substrate T transferred via the transfer path 31 is mounted on the substrate mount TM.

The substrate transfer mechanism 5 receives the substrate T mounted on the substrate mount TM from a movement mechanism (not shown) that can move in the X direction, moves in an X direction and the Y direction inside the substrate supply/storage module A and the resin molding module B, and transfers the substrate T to a below-described molding mold 7 of the resin molding module B. Further, the substrate transfer mechanism 5 moves in the X direction and the Y direction inside the substrate supply/storage module A and the resin molding module B, receives the resin molded substrate W (resin molded product) molded by the below-described molding mold 7 of the resin molding module B, and transfers the resin molded substrate W to the substrate supply/storage module A.

On the molded substrate mount WM, the resin molded substrate W moved from the substrate transfer mechanism 5 is mounted by the movement mechanism (not shown) that can move in the X direction. The transfer path 32 is used to transfer the resin molded substrate W mounted on the molded substrate mount WM in the Y direction.

As an example, the transfer path 31 or 32 may be configured by a pair of rails, each of which is formed with a groove having a C-shaped cross section and which are arranged so that openings of the grooves face each other. In the case of this example, by arranging the substrate T or the resin molded substrate W so that end portions thereof are fit into the grooves of the rails, it is possible to slidingly move the substrate T or the resin molded substrate W in a longitudinal direction of the rails (corresponding to the Y direction in FIG. 1) along the rails.

As will be described later, the inspection device 4 inspects appearance of the resin molded substrate W, which has been moved from the molded substrate mount WM and is being transferred via the transfer path 32. The substrate storage 2 stores the resin molded substrate W transferred from the transfer path 32.

The controller COM includes a CPU (Central Processing Unit), a RAM (Random Access Memory), a ROM (Read Only Memory), and the like, and is configured to control individual components according to information processing. The controller COM is configured to control at least the inspection device 4, and may be configured to control the entire resin molding apparatus 100. Details of controlling the operation of the inspection device 4 by the controller COM will be described later.

The resin molding module B, which is a resin molding part for molding a resin on the substrate T, includes the molding mold 7 and a mold clamping mechanism 6 for clamping the molding mold 7. The resin molding module B manufactures the resin molded substrate W (resin molded product) by a compression molding method using a resin material P that is supplied by the resin material supply C. A surface of the molding mold 7 in which the resin molded substrate W is molded has been subjected to an embossing process so that the resin molded substrate W can be easily released from the molding mold 7. Examples of the embossing process include satin-finishing and the like.

For example, the molding mold 7 for compression molding includes an upper mold and a lower mold disposed to face each other, and may have a configuration in which the substrate T is supplied to the upper mold and the resin material P is supplied to the lower mold. In the case of this example, the lower mold may include a bottom surface member constituting a cavity bottom surface and a side surface member constituting a cavity side surface, and may have a configuration in which the bottom surface member and the side surface member can be relatively slidable. Moreover, in this lower mold configuration, surfaces of the bottom surface member and the side surface member, which define a cavity, have been subjected to an embossing process.

The resin material supply module C includes a moving table 8, a resin material accommodator 9 mounted on the moving table 8, a resin material supply 10 configured to supply the resin material P to the resin material accommodator 9, and a resin material transfer mechanism 11 configured to transfer the resin material accommodator 9 and supply the resin material P to the molding mold 7 of the resin molding module B. The moving table 8 is configured to move in the X direction and the Y direction inside the resin material supply module C. The resin material transfer mechanism 11 moves in the X direction and the Y direction inside the resin material supply module C and the resin molding module B. Thus, the resin material transfer mechanism 11 transfers the resin material accommodator 9 accommodating the resin material P to the molding mold 7 to supply the resin material P to the molding mold 7. As an example, the resin material accommodator 9 may have a configuration in which a release film is disposed so as to close an open lower surface of a frame-shaped member.

### Configuration of Inspection Device 4

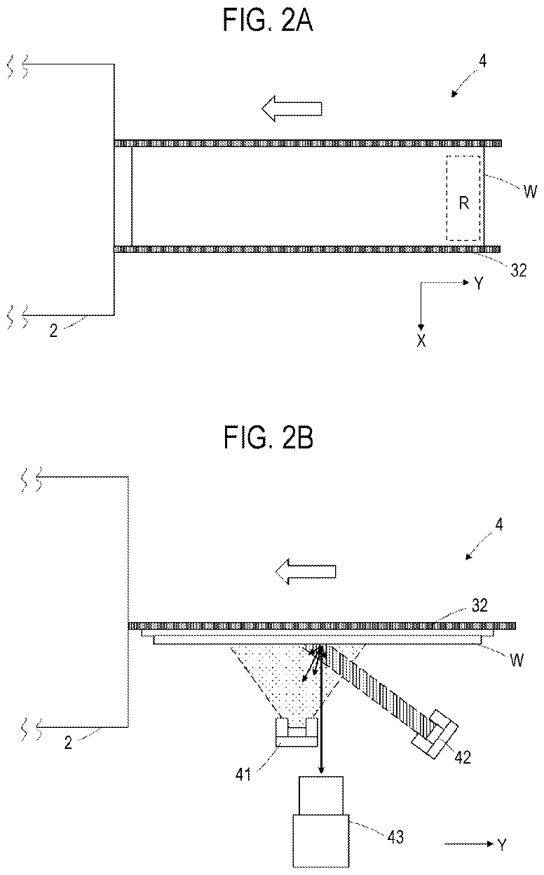

Next, the inspection device 4 according to the present embodiment will be described in detail. FIG. 2A is a plan view of the inspection device 4, and FIG. 2B is a side view of the inspection device 4.

The inspection device 4 is configured to inspect appearance of the resin molded substrate W (resin molded product) that is moving along the transfer path 32 toward the substrate storage 2 after being resin-molded in the resin molding module B (resin molding part). As shown in FIGS. 2A and 2B, the inspection device 4 includes a first light source 41, a second light source 42, and a camera 43. When the resin molded substrate W is transferred via the transfer path 32, a package surface thereof faces downward. In the resin molded substrate W of the present embodiment, a semiconductor chip is mounted on one surface of the substrate T, and the one surface is used as a resin-encapsulated package surface. Since the resin molded substrate W is formed by the molding mold 7 subjected to an embossing process, a wrinkle pattern is formed on the surface of the resin molded substrate W.

The first light source 41 is a diffusion light source configured to irradiate diffused light through a diffusion plate. The first light source 41 is disposed coaxially or in parallel with the camera 43 to face the resin molded substrate W, and irradiates light from a direction perpendicular to the package surface of the resin molded substrate W.

The second light source 42 is a focusing light source configured to focus light at a certain point via a focusing optical component. The second light source 42 is disposed obliquely with respect to the camera 43 and the resin molded substrate W, and irradiates light from an oblique direction with respect to the package surface of the resin molded substrate W. Both the first light source 41 and the second light source 42 are white light sources.

The camera 43 takes an image of the package surface of the resin molded substrate W which is being transferred via the transfer path 32. Light is irradiated simultaneously from the first light source 41 and the second light source 42 and reflected from the resin molded substrate W, and the camera 43 captures the reflected light for each inspection range R. Data obtained by dividing the package surface of the resin molded substrate W into inspection ranges R and taking images of the respective inspection ranges R is created as a single piece of image data. The camera 43 captures specularly reflected light and diffusively reflected light, which are reflected light of the light irradiated on the package surface of the resin molded substrate W. At this time, the camera 43 captures the specularly reflected light which is the reflected light of the light irradiated by the first light source 41 and the diffusively reflected light which is the reflected light of the light irradiated by the second light source 42. Examples of the camera 43 include a line scan camera and an area scan camera. The inspection range R is a range captured by one imaging operation of the camera 43. That is, the inspection range R may be one scan line region for a line scan camera, and may be a region of a plurality of scan lines for an area scan camera.

In the present embodiment, the appearance of the package surface on the lower surface of the resin molded substrate W is inspected. Therefore, the first light source 41, the second light source 42, and the camera 43 are disposed below the transfer path 32.

The controller COM inspects the appearance of the resin molded substrate W based on the image data obtained by taking images of the respective inspection ranges R by the camera 43. When a line scan camera is used as the camera 43, two-dimensional image data can be obtained by acquiring plural pieces of one-dimensional image data by the imaging operation of the line scan camera and synthesizing the plural pieces of one-dimensional image data. The controller COM detects presence or absence of a defect based on defect information on the package surface, which is set in advance. When there is a defect, the controller COM identifies a location of the defect on the package surface of the resin molded substrate W and determines whether or not a size of the defect falls within a predetermined range. As used herein, the term “defect” includes a void generated by poor resin molding, a shallow scratch generated during transferring or drying the resin material P, and the like.

### Operation of Inspection Device 4

In the inspection device 4 described above, the resin molded substrate W moving from the molded substrate mount WM toward the substrate storage 2 along the transfer path 32 is irradiated with light by the first light source 41 and the second light source 42 and the reflected light (specularly reflected light and diffusively reflected light) is captured by the camera 43. The controller COM inspects the appearance of the resin molded substrate W based on the single piece of image data created from the images taken for the respective inspection ranges R by the camera 43.

In this regard, when the line scan camera is used as the camera 43 and disposed close to the first light source 41, the entire imaging region can be set to a region closer to the camera 43 than when the area scan camera is used. Therefore, in the case where the line scan camera is used, even when light is irradiated in a vertical direction from the first light source 41, which is a diffusion light source, a larger amount of components of the specularly reflected light from the resin molded substrate W can be caused to be incident on the camera 43 than in the case where the area scan camera is used.

In addition, when the area scan camera is used as the camera 43, the inspection device can be configured at a lower cost than when the line scan camera is used.

### COMPARATIVE EXAMPLES

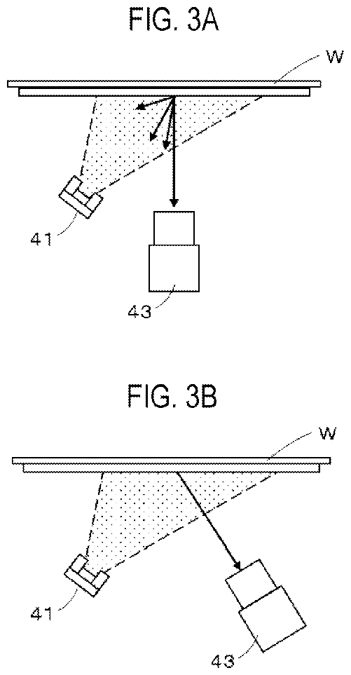

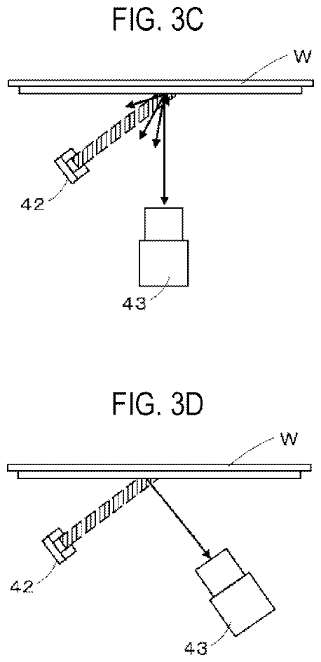

FIGS. 3A to 3D show comparative examples, in each of which an inspection device is provided with one type of light source.

FIG. 3A shows Comparative Example a in which the first light source 41 as a diffusion light source irradiates light obliquely on the resin molded substrate W and the camera 43 captures diffusively reflected light. FIG. 3B shows Comparative Example b in which the first light source 41 irradiates light obliquely on the resin molded substrate W and the camera 43 captures specularly reflected light. FIG. 3C shows Comparative Example c in which the second light source 42 as a focusing type light source irradiates light obliquely on the resin molded substrate W and the camera 43 captures diffusively reflected light. FIG. 3D shows Comparative Example d in which the second light source 42 irradiates light obliquely on the resin molded substrate W and the camera 43 captures specularly reflected light.

### Inspection Results

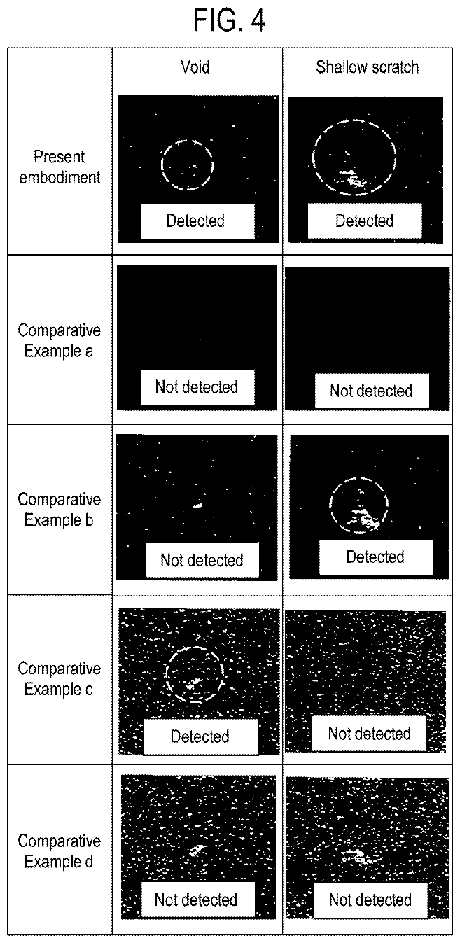

FIG. 4 shows inspection results obtained by the inspection device provided with two types of light sources (the present embodiment) and by the inspection devices provided with one type of light source as shown in FIGS. 3A to 3D (Comparative Examples a to d). A void and a shallow scratch, which are types of defects occurring on the package surface of the resin molded substrate W, were inspected.

As shown in FIG. 4, the present embodiment can detect both a void and a shallow scratch, which are types of defects.

The results are considered as follows. First, description will be made on a case where the first light source 41, which is a diffusion light source, irradiates light on the resin molded substrate W in the vertical direction and the reflected light is observed by the camera 43 from the vertical direction. When diffused light is irradiated from the first light source 41, relatively weak light is irradiated to a relatively large area. Then, by observing the light by the camera 43 from the vertical direction, specularly reflected light of the vertically incident light can be observed. This specularly reflected light is stronger than diffusively reflected light. Thus, both the contrast due to reflection of light from a wrinkle pattern on the package surface of the resin molded substrate W and the contrast due to reflection of light from a shallow scratch have values that can be sufficiently observed by the camera 43. Therefore, the wrinkle pattern and the shallow scratch can be observed and distinguished from each other, and it is possible to inspect the shallow scratch.

Next, description will be made on a case where the second light source 42, which is a focusing light source, irradiates light on the resin molded substrate W in an oblique direction and the reflected light is observed by the camera 43 from the vertical direction. When the focused light is irradiated from the second light source 42, relatively strong light is irradiated to a relatively narrow area. Then, by observing the light by the camera 43 from the vertical direction, which is different from the direction in which light is irradiated by the second light source 42, diffusively reflected light can be observed. This diffusively reflected light is weaker than specularly reflected light. Thus, the contrast due to reflection of light in the vicinity of a defect such as a void or the like on the package surface of the resin molded substrate W has a value that can be sufficiently observed by the camera 43. Therefore, it is possible to inspect the defect such as a void or the like. Further, even when the first light source 41 irradiates light on the resin molding substrate W in the vertical direction while the second light source 42 irradiates light on the resin molding substrate W in the oblique direction, and the reflected light is observed by the common camera 43 from the vertical direction, it is possible to observe both the specularly reflected light generated by the first light source 41 and the diffusively reflected light generated by the second light source 42, as long as intensities of the specularly reflected light and the diffusively reflected light are not changed significantly.

On the other hand, in Comparative Example a, when the first light source 41 irradiates light obliquely on the resin molded substrate W and the diffusively reflected light is captured by the camera 43 from the vertical direction, neither a void nor a shallow scratch can be detected.

In Comparative Example b, when the first light source 41 irradiates light obliquely on the resin molded substrate W and the specularly reflected light is captured by the camera 43 from an opposite oblique direction, a shallow scratch on the package surface of the resin molded substrate W may be detected, but a void cannot be detected.

In Comparative Example c, when the second light source 42 irradiates light obliquely on the resin molded substrate W and the diffusively reflected light is captured by the camera 43 from the vertical direction, a void may be detected, but a shallow scratch cannot be detected.

In Comparative Example d, when the second light source 42 irradiates light obliquely on the resin molded substrate W and the camera 43 captures an image from an opposite oblique direction, neither a void nor a shallow scratch can be detected.

Therefore, the inspection device provided with one type of light source as in Comparative Examples a to d cannot detect a plurality of defects at the same time in a common inspection process. However, the inspection device according to the present embodiment can detect a plurality of defects at the same time in a common inspection process.

### Method of Manufacturing Resin Molded Product

A method of manufacturing a resin molded product (resin molded substrate W) by using the resin molding apparatus 100 shown in FIG. 1 will be described.

A substrate supply process of supplying the substrate T to the molding mold 7 is performed. In the substrate supply/storage module A, the substrate T is transferred from the substrate supply 1 to the substrate mount TM via the transfer path 31. The movement mechanism (not shown) delivers the substrate T mounted on the substrate mount TM to the substrate transfer mechanism 5. The substrate transfer mechanism 5 transfers the received substrate T to the resin molding module B, and supplies the substrate T to the molding mold 7 in the resin molding module B.

In addition, a resin material supply process of supplying the resin material P to the molding mold 7 is performed. In the resin material supply module C, the resin material P is supplied from the resin material supply 10 to the resin material accommodator 9 mounted on the moving table 8. The moving table 8 delivers the resin material P accommodated in the resin material accommodator 9 to the resin material transfer mechanism 11. The resin material transfer mechanism 11 transfers the received resin material P to the resin molding module B, and supplies the resin material P to the molding mold 7 in the resin molding module B. Either the substrate supply process or the resin material supply process may be performed first, or the substrate supply process and the resin material supply process may be at least partially performed at the same time.

A resin molding process is performed after the substrate supply process and the resin material supply process. In the resin molding module B, in a state in which the substrate T and the resin material P are supplied to the molding mold 7, the mold clamping mechanism 6 clamps the molding mold 7 to perform resin molding. After performing the resin molding, the mold clamping mechanism 6 opens the molding mold 7. The substrate transfer mechanism 5 takes out the resin molded substrate W, which is a resin molded product in which a package is formed on the substrate T by the resin molding process, from the molding mold 7 which has been opened.

An inspection process is performed after the resin molding process. The substrate transfer mechanism 5 transfers the taken-out resin molded substrate W from the resin molding module B to the substrate supply/storage module A. In the substrate supply/storage module A, the movement mechanism (not shown) transfers the resin molded substrate W from the substrate transfer mechanism 5 to the molded substrate mount WM. The resin molded substrate W mounted on the molded substrate mount WM is inspected by the inspection device 4 as described above while being transferred via the transfer path 32, and is then stored in the substrate storage 2. Based on the inspection result in the inspection process, it is possible to determine whether the resin molded substrate W is good or poor.

### Other Embodiments

The idea of the above-described embodiment is not limited to the embodiment described above. Hereinafter, other embodiments to which the idea of the above-described embodiment is applicable will be described.

In the resin molding apparatus 100 of the above-described embodiment, the resin molded substrate W (resin molded product) is manufactured by a compression molding method. However, the resin molded substrate W (resin molded product) may be manufactured not only by the compression molding method but also by a transfer molding method.

In the resin molding apparatus 100 of the above-described embodiment, the surface of the molding mold 7 of the resin molding module B has been subjected to the embossing process. However, the surface of the molding mold 7 does not necessarily have to be subjected to the embossing process.

In the inspection device 4 of the above-described embodiment, the first light source 41, the second light source 42, and the camera 43 are disposed below the transfer path 32, and the package surface in the lower surface of the resin molded substrate W is inspected. However, in a case of inspecting a package surface on an upper surface of the resin molded substrate W, the first light source 41, the second light source 42, and the camera 43 may be disposed above the transfer path 32.

In the inspection device 4 of the above-described embodiment, the resin molded substrate W which is moving in the transfer path 32 is inspected. However, the resin molded substrate W may be inspected in a stationary state without being moved. In this case, the optical system including the first light source 41, the second light source 42, and the camera 43 may be moved for inspection. In addition, both the resin molded substrate W and the optical system may be moved for inspection.

In the inspection device 4 of the above-described embodiment, white light sources are used as the first light source 41 and the second light source 42. However, light sources having other wavelength ranges may be used as the first light source 41 and the second light source 42.

In the inspection device 4 of the above-described embodiment, the first light source 41, which is a diffusion light source, irradiates light in the direction perpendicular to the resin molded substrate W. However, the light irradiation direction of the first light source 41 does not have to be strictly perpendicular to the resin molded substrate W, and may be any direction as long as defects can be detected by the specularly reflected light generated by the first light source 41 and the diffusively reflected light generated by the second light source 42, respectively.

In the inspection device 4 of the above-described embodiment, the camera 43 creates the data obtained by dividing the package surface of the resin molded substrate W into inspection ranges R and taking images of the respective inspection ranges R as a single piece of image data. However, the camera 43 may create data obtained by taking an image of the entire inspection range, rather than taking images of the respective divided inspection ranges R, as a single piece of image data. In addition, the camera 43 may create data obtained by taking images of the respective divided inspection ranges R as plural pieces (two pieces or more) of image data.

### Configuration and Effect of Embodiments

The inspection device of the above-described embodiments includes a first light source configured to emit light through a diffusion plate, a second light source configured to emit light through a focusing optical component, and a camera configured to take an image of a resin molded substrate irradiated with light from the first light source and the second light source. According to this inspection device, it is possible to detect various types of defects on the surface of the resin molded product, which is a workpiece, in a common inspection process.

As a specific configuration of the inspection device, an object to be inspected may be a resin molded substrate having a wrinkle pattern formed on at least a part of a surface thereof. According to this configuration, even for a resin molded substrate having a wrinkle pattern formed on a package surface, which is a resin portion, it is possible to detect a defect separately from the wrinkle pattern.

As a specific configuration of the inspection device, the camera may be a line scan camera. According to this configuration, the entire imaging region can be set to a region closer to the camera than when an area scan camera is used. Thus, even when the first light source, which is a diffusion light source, irradiates light in the vertical direction, a large amount of components of the specularly reflected light from the resin molded substrate can be caused to be incident on the camera.

As a specific configuration of the inspection device, inspection may be performed while moving the resin molded substrate. According to this configuration, movement of the optical system can be suppressed. Therefore, it is possible to reduce a frequency of optical adjustment.

Further, the resin molding apparatus of the above-described embodiments includes the resin molding part configured to resin-mold a substrate and the inspection device described above. According to this resin molding apparatus, various types of defects on the surface of a resin molded product (resin molded substrate) can be detected in a common inspection process. Thus, it is also possible to perform an efficient appearance inspection and to improve productivity.

As a specific configuration of the resin molding apparatus, the resin molding part may include a molding mold which has a surface having been subjected to an embossing process. According to this configuration, even when a wrinkle pattern is formed on the surface of the object to be inspected by subjecting the surface of the molding mold to the embossing process to improve releasability, it is possible to detect defects separately from the wrinkle pattern.

Further, in the method of manufacturing a resin molded product according to the above-described embodiments, the resin molded product is manufactured by the resin molding process of performing resin molding in the resin molding part and the inspection process of inspecting, by the above-described inspection device, the resin molded substrate molded in the resin molding process. With this method of manufacturing a resin molded product, various types of defects on the surface of a resin molded product (resin molded substrate) can be detected in a common inspection process. Thus, it is possible to perform an efficient appearance inspection and to improve productivity.

The embodiments of the present disclosure have been described above by way of example. That is, the detailed description and the accompanying drawings have been disclosed for the sake of exemplary description. Thus, the components described in the detailed description and the accompanying drawings may include components that are not essential for solving the problem. Therefore, the non-essential components should not be immediately determined to be essential merely because those non-essential components are described in the detailed description and the accompanying drawings.

According to the present disclosure in some embodiments, it is possible to provide a technique capable of detecting various types of defects on a surface of a resin molded product, which is a workpiece, in a common inspection process.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An inspection device, comprising:
a first light source configured to emit light through a diffusion plate;
a second light source configured to emit light through a focusing optical component; and
a camera configured to take an image of a resin molded substrate irradiated with the light from the first light source and the second light source.

2. The inspection device of claim 1, wherein a wrinkle pattern is formed on at least a part of a surface of the resin molded substrate.

3. The inspection device of claim 1, wherein the camera is a line scan camera.

4. The inspection device of claim 1, wherein the inspection device inspects the resin molded substrate while moving the resin molded substrate.

5. A resin molding apparatus, comprising:
a resin molding part configured to resin-mold a substrate; and
the inspection device of claim 1.

6. The resin molding apparatus of claim 5, wherein the resin molding part includes a molding mold which has a surface having been subjected to an embossing process.

7. A method of manufacturing a resin molded product by using the resin molding apparatus of claim 5, the method comprising:
a resin molding process of performing resin molding in the resin molding part; and
an inspection process of inspecting, by the inspection device, the resin molded substrate molded in the resin molding process.
